(19) United States
(12) Patent Application Publication
(10) Pub. No.: US 2024/0387756 A1
(43) Pub. Date: Nov. 21, 2024

(54) TRANSPARENT CONDUCTIVE ENCAPSULANT FOR PHOTOELECTROCHEMICAL APPLICATIONS AND METHODS THEREFOR

(71) Applicants: Alliance for Sustainable Energy, LLC, Golden, CO (US); Colorado School of Mines, Golden, CO (US)

(72) Inventors: Ann London GREENAWAY, Lakewood, CO (US); Grace Ann ROME, Golden, CO (US); Adele Clare TAMBOLI, Golden, CO (US); Talysa Renae KLEIN, Greybull, WY (US)

(21) Appl. No.: 18/668,718

(22) Filed: May 20, 2024

Related U.S. Application Data
(60) Provisional application No. 63/503,218, filed on May 19, 2023.

(51) Int. Cl. H01L 31/0203; H01L 31/0224; H01L 31/18

(52) U.S. Cl. CPC H01L 31/0203; H01L 31/022491; H01L 31/1884

(57) ABSTRACT

Described herein are devices and methods that provide for the protection of photoelectrodes by encapsulating the surface exposed to the electrolyte with a transparent polymer containing dispersed transition metal coated polymer particles or spheres. Advantageously, these transparent conductive encapsulants (TCEs) provide significant conductivity while providing high transparency, allowing more photons to reach the photoelectrode, resulting in higher efficiency and longer device lifetimes.

### CROSS-REFERENCE TO RELATED APPLICATIONS

This application claims priority from U.S. Provisional Patent Application No. 63/503,218 filed on May 19, 2023, the contents of which are incorporated herein by reference in their entirety.

### CONTRACTUAL ORIGIN

This invention was made with government support under Contract No. DE-AC36-08GO28308 awarded by the Department of Energy. The government has certain rights in the invention.

### BACKGROUND

The use of photoelectrochemical cells for the generation of sustainable fuel, including carbon dioxide reduction, represents an important pathway for the reduction of greenhouse gases and generation of sustainable energy. However, many advanced semiconductors used in photoelectrochemical applications are susceptible to degradation in the presence of aqueous electrolytes and illumination, resulting in both economic and operational concerns for photoelectrochemical fuel production. While methods of protecting the electrodes have been proposed, many of these strategies decrease the amount of illumination that can reach the electrode, decrease the electrical conductivity through the protective layer, or both. Additionally, many other proposed methods of protection are highly material-specific. Accordingly, it can be seen by the foregoing that there remains a need in the art for new conductive encapsulant layers for use in photoelectrochemical sustainable fuel generation with high transparency and conductivity and useful with a variety of different materials.

### SUMMARY

Described herein are devices and methods that provide for the protection of photoelectrodes by encapsulating the surface exposed to the electrolyte with a transparent polymer containing dispersed transition metal coated polymer particles or spheres. Advantageously, these transparent conductive encapsulants (TCEs) provide significant conductivity while providing high transparency, allowing more photons to reach the photoelectrode, resulting in higher efficiency and longer device lifetimes.

In an aspect, provided is an encapsulant comprising: a) a transparent polymer; and b) a plurality of transition metal coated poly (methyl methacrylate) (PMMA) or other rigid polymer particles embedded in the transparent polymer; wherein the plurality of transition metal coated PMMA particles provide a conductive pathway through the transparent polymer. Other rigid polymers include any polymer with the necessary compressive strength to substantially maintain their form under the pressures described herein, for example, poly vinyl chloride, high density polyethylene or polystyrene.

In an aspect, provided is a device comprising: a) a photoelectrode; and b) an encapsulant comprising: i) a transparent polymer comprising EVA; and ii) a plurality of transition metal coated poly (methyl methacrylate) (PMMA) or other rigid polymer particles embedded in the transparent polymer; wherein the plurality of transition metal coated PMMA particles provide a conductive pathway through the transparent polymer; wherein a first surface of the encapsulant is proximate to a surface of the photoelectrode.

In an aspect, provided is a method comprising: a) providing a rigid bottom surface; b) depositing a solution comprising a plurality of transition metal coated PMMA spheres in a dissolved polymer on the surface of the bottom surface; c) applying a top surface barrier, wherein the solution is positioned between the bottom surface and the top surface barrier; d) evaporating a solvent from the dissolved polymer to form a solid transparent polymer with dispersed transition metal coated PMMA spheres; and e) applying a pressure to the solid transparent polymer, thereby exposing a portion of the dispersed transition metal coated PMMA spheres and generating a transparent conductive encapsulant. The method may further comprise: f) removing the rigid bottom surface and the top surface barrier from the solid transparent polymer with dispersed transition metal coated PMMA spheres; and g) applying the solid transparent polymer with dispersed transition metal coated PMMA spheres to a photoelectrode. In some cases, a blade may be used to apply the polymer solution evenly across the rigid bottom surface, prior to the addition of a top surface barrier used for evenly applying pressure. The step of removing may be in the form of peeling away the transparent polymer.

The transparent polymer may comprise ethyl vinyl acetate, a silicone, a polyurethane, or a combination thereof. The transition metal in the transition metal coating may comprise Cu, Ag, Au, Pd, Pt, Al or a combination thereof.

A portion of the transition metal coated PMMA particles may be exposed in a top surface of a bottom surface of the transparent polymer, for example by applying pressure to the encapsulant. The transition metal coated PMMA particles may have a coverage or percentage surface area of the encapsulant selected from the range of 3% to 25%, 5% to 25%, 10% to 25%, 3% to 50%, or optionally, greater than or equal to 10% or 15%.

The thickness of the encapsulant may be about equal to the effective diameter to the transition metal coated PMMA particles, for example, to allow for conduction through the encapsulant. The transition metal coated PMMA particles may be substantially spherical. The particles may have other defined shapes such as being substantially cylinders, ovoids, etc. The particle shape may change during compression to expose the particles to the surface of the transparent polymer.

The top surface barrier and/or the bottom rigid surface may comprise smooth polytetrafluoroethylene (PTFE) and glass. The pressure may be less than or equal to 10 psi, 7 psi, or optionally 6 psi (approximately 68.9 kPa, 48.3 kPa and 41.4 kPa, respectively).

### BRIEF DESCRIPTION OF DRAWINGS

Some embodiments are illustrated in referenced figures of the drawings. It is intended that the embodiments and figures disclosed herein are to be considered illustrative rather than limiting.

FIG. 1A provides an example schematic of TCE operation on an electrode. FIG. 1B provides magnification of FIG. 1A to show the movement of charge carriers from generation in the photoabsorber to the electrochemical reaction in solution. FIG. 1C provides an example schematic of the lamination process in cross-section, including the lamination frame with provides stability to the whole lamination process and the Teflon liners at the top and bottom which protect the laminator.

FIGS. 2A-2C provide optical microscope images of as-sawn Si laminated from a single TCE sheet at different pressures. The calculated coverages for each sample are given with the overall average coverage being 2.4±0.7%. Reported uncertainty is the standard deviation from a minimum of five images across each sample. Scale bars are 50 μm (black) and 250 μm (white). FIG. 2A shows 3 psi, FIG. 2B shows 6 psi, and FIG. 2C shows 9 psi.

FIGS. 3A-3B show unstirred CVs of TCE titanium-coated as-sawn Si (TCE|Ti|Si) electrodes laminated at different pressures. The TCE|Ti|Si electrode traces correlate to the circles in the inset scale bars, showing Ag-PMMA coverage in the TCE. A planar Si coated Ag (p-Ag|Si, purple dashed line, right axis) is shown for comparison. CVs were collected at 20 mV/s, scanning negative from −0.1 V to−0.9 V, just before the onset of the MV^{2+/+} reduction based on the p-Ag|Si electrode. The electrolyte was 45 mM MV (no reduced form initially present) in 0.5 M K₂SO₄, with a Pt counter electrode and saturated calomel reference electrode. While uncertainty in coverage is not directly represented in this figure, all electrodes shown had standard deviations of <22%. FIG. 3A shows 6 psi and FIG. 3B shows 7 psi.

FIG. 4A shows stirred current density at −0.8 V vs SCE as a function of coverage for each TCE|Ti|Si electrode, measured under the same MV^{2+/+} conditions used for FIGS. 3A-3B. The current density is normalized to the expected active area of the spheres, coverage x geometric electrode area. A stirred CV of the p-Ag|Si electrode was measured to obtain the 100% coverage point. The p-Ag|Si electrode was then masked (see SI) and measured again with 29.5% of the original surface exposed to obtain that data point. Error in coverage was calculated based on the standard deviation of the TCE coverage (given in Table 1); error in current density includes coverage error and the standard deviation of the current at −0.8±0.01 V vs SCE. FIG. 4B shows a schematic of the possible difference between areal coverage of the Ag-PMMA spheres and the area exposed to solution, as well as the possible protrusion of EVA at the edges of the sphere when lamination pressures are low. FIG. 4C provides optical microscope images of a TCE|Ti|Si electrode driven to oxidizing potentials (+0.2 V vs SCE), highlighting the difference between the areal coverage (defined by the silver area) and the solution contact (black, oxidized). As in FIG. 2B, a few spheres are cracked, but most are intact.

FIG. 5 provides an exemplary cross-sectional schematic of a TCE in contact with a photoelectrode providing protection from degradation from an electrolyte.

FIGS. 6A provides a schematic of TCE lamination with two release layers to allow the laminated TCE sheet to be free-standing. FIG. 6B provides a pinhole detection apparatus image of a TCE sheet laminated as in FIG. 6A, showing no bright spots that would indicate holes. The white dotted box indicates the edge of the supporting metal sheet below the TCE, and the red dotted box indicates where the TCE sits directly above the hydrogen flow.

FIG. 7 provides a Si photoelectrode where the TCE was breached by solution during photoelectrochemical measurements. The red circle indicates a small amount of electrolyte under the TCE, which moved with gravity. The discoloration in the corner may be the result of additional penetration and reaction. The contrast in this image has been altered to make the appearance of the electrolyte clearer in the photograph.

FIGS. 8A-8F illustrate performance over eight hours for GaInP and Si photoelectrodes for MV^{2+/+}. For GaInP, CA of bare (FIG. 8A) and TCE-protected (21±6% coverage) (FIG. 8B) photoelectrodes was performed at −0.25 V vs Ag/AgCl. FIG. 8C provides photovoltage of bare and TCE-protected GaInP photoelectrodes. At one hour, the illuminated V_{OC} of the bare GaInP photoelectrode was 0.38 V vs Ag/AgCl, compared to the TCE GaInP at −0.041 V vs Ag/AgCl (see FIG. 9 for complete V_{OC}). After eight hours, the bare and TCE GaInP have the nearly the same photovoltage, 0.32 and 0.29 V vs Ag/AgCl respectively. For Si, CA of bare (FIG. 8D and TCE-protected (30±6% coverage) (FIG. 8E) photoelectrodes was performed at −0.6 V vs Ag/AgCl. FIG. 8F provides photovoltage of bare and TCE-protected Si photoelectrodes. At one hour, the illuminated V_{OC} of the bare Si photoelectrode was −0.04 V vs Ag/AgCl, compared to the TCE Si at −0.45 V vs Ag/AgCl (see FIG. 9). CA current transients (FIGS. 8A, 8B, 8D and 8E are a result of intermittent V_{OC} and CVs; markers over the raw CA data indicate the average photocurrent over the last 30 minutes of each hour to show photocurrent stability over time.

FIGS. 9A-9D provide illuminated cyclic voltammetry (CV, IUPAC convention) and open-circuit (V_{OC}) measurements comparing bare and TCE-protected photoelectrodes in methyl viologen. FIG. 9A shows initial and final CVs and FIG. 9B shows illuminated and dark V_{OC} for GaInP photoelectrodes, measured after every CA. FIG. 9C shows initial and final CVs and FIG. 9D shows illuminated and dark V_{OC} for Si photoelectrodes, measured after every CA. The applied potentials for the extended CAs in the main text were chosen to be negative of the onset of the reduction of methyl viologen: −0.25 vs Ag/AgCl for GaInP and −0.6 V vs Ag/AgCl for GaInP and Si, respectively.

FIGS. 10A-10C provide performance over forty-six hours for Si photoelectrodes in pH 11 buffer electrolyte. CAs of bare (FIG. 10A) and TCE-protected (33±6.6%) (FIG. 10B) photoelectrodes were performed at −0.65 V vs Ag/AgCl (note the difference in photocurrent scale between FIG. 10A and FIG. 10B). FIG. 10C shows photovoltage of bare and TCE-protected Si photoelectrodes in pH 11 buffer. At one hour, the illuminated V_{OC} of the bare Si photoelectrode was −0.26 V vs Ag/AgCl, compared to the TCE Si at −0.51 V vs Ag/AgCl (FIG. 11) As in FIG. 8, markers over the raw CA data (FIGS. 8A-8B) indicate the average photocurrent over the last 30 minutes of each hour.

FIGS. 11A-11B provide illuminated CV (IUPAC convention) and V_{OC} measurements comparing bare and TCE-protected Si photoelectrodes performing hydrogen evolution in pH 11 buffer. FIG. 11A shows initial, eight-hour, and forty-six-hour CVs and FIG. 11B shows illuminated and dark V_{OC} for Si photoelectrodes measured after every CA. The applied potentials for the extended CAs in the main text were chosen to be negative of the onset of the hydrogen evolution reaction at −0.65 V vs Ag/AgCl.

FIG. 12A shows E_{1/2} and FIG. 12B shows peak separation for the reduction and oxidation peaks of MV²⁺/MV⁺ with increasing Ag-PMMA coverage in TCE|Ti|Si electrodes, extracted from unstirred CVs (FIG. 3).

FIGS. 13A-13D shows selected stirred voltammetry for the TCE|Ti|Si extracted data presented in FIG. 4A. 6 psi (FIG. 13A) and 7 psi (FIG. 13B) electrodes, normalized to geometric area of the electrode; the same 6 psi (FIG. 13C) and 7 psi (FIG. 13D) electrodes normalized to the active area (coverage×geometric area) of the electrodes.

### REFERENCE NUMERALS

100 Encapsulant
110 Transparent polymer
120 Transition metal coated PMMA particle
130 Photoelectrode
140 Electrolyte

### DETAILED DESCRIPTION

The embodiments described herein should not necessarily be construed as limited to addressing any of the particular problems or deficiencies discussed herein. References in the specification to “one embodiment”, “an embodiment”, “an example embodiment”, “some embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

As used herein the term “substantially” is used to indicate that exact values are not necessarily attainable. By way of example, one of ordinary skill in the art will understand that in some chemical reactions 100% conversion of a reactant is possible, yet unlikely. Most of a reactant may be converted to a product and conversion of the reactant may asymptotically approach 100% conversion. So, although from a practical perspective 100% of the reactant is converted, from a technical perspective, a small and sometimes difficult to define amount remains. For this example of a chemical reactant, that amount may be relatively easily defined by the detection limits of the instrument used to test for it. However, in many cases, this amount may not be easily defined, hence the use of the term “substantially”. In some embodiments of the present invention, the term “substantially” is defined as approaching a specific numeric value or target to within 20%, 15%, 10%, 5%, or within 1% of the value or target. In further embodiments of the present invention, the term “substantially” is defined as approaching a specific numeric value or target to within 1%, 0.9%, 0.8%, 0.7%, 0.6%, 0.5%, 0.4%, 0.3%, 0.2%, or 0.1% of the value or target.

As used herein, the term “about” is used to indicate that exact values are not necessarily attainable. Therefore, the term “about” is used to indicate this uncertainty limit. In some embodiments of the present invention, the term “about” is used to indicate an uncertainty limit of less than or equal to ±20%, ±15%, ±10%, ±5%, or ±1% of a specific numeric value or target. In some embodiments of the present invention, the term “about” is used to indicate an uncertainty limit of less than or equal to ±1%, ±0.9%, ±0.8%, ±0.7%, ±0.6%, ±0.5%, ±0.4%, ±0.3%, ±0.2%, or ±0.1% of a specific numeric value or target.

The provided discussion and examples have been presented for purposes of illustration and description. The foregoing is not intended to limit the aspects, embodiments, or configurations to the form or forms disclosed herein. In the foregoing Detailed Description for example, various features of the aspects, embodiments, or configurations are grouped together in one or more embodiments, configurations, or aspects for the purpose of streamlining the disclosure. The features of the aspects, embodiments, or configurations, may be combined in alternate aspects, embodiments, or configurations other than those discussed above. This method of disclosure is not to be interpreted as reflecting an intention that the aspects, embodiments, or configurations require more features than are expressly recited in each claim. Rather, as the following claims reflect, inventive aspects lie in less than all features of a single foregoing disclosed embodiment, configuration, or aspect. While certain aspects of conventional technology have been discussed to facilitate disclosure of some embodiments of the present invention, the Applicants in no way disclaim these technical aspects, and it is contemplated that the claimed invention may encompass one or more of the conventional technical aspects discussed herein. Thus, the following claims are hereby incorporated into this Detailed Description, with each claim standing on its own as a separate aspect, embodiment, or configuration.

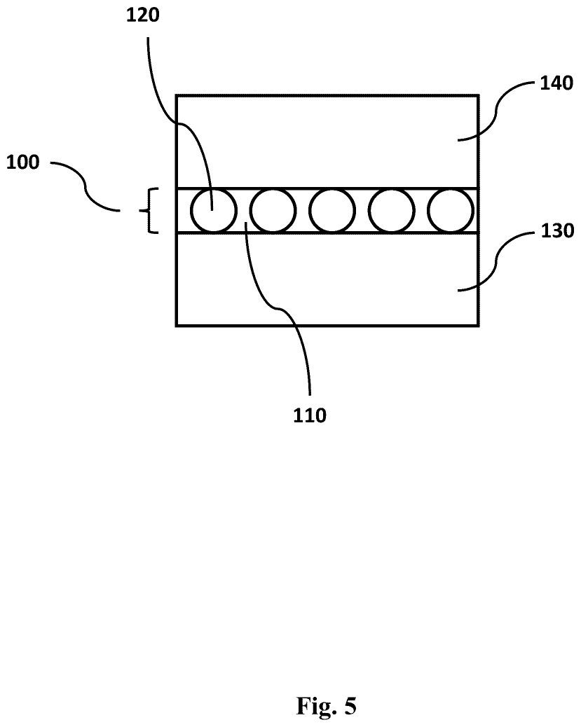

FIG. 5 provides an example schematic of a transparent conductive encapsulant 100 in use in a photoelectrochemical cell. The encapsulant 100 is positioned between the photoelectrode 130 and the electrolyte 140, protecting the photoelectrode 130 from degradation due to exposure to the electrolyte 140. The encapsulant 100 comprises a plurality of transition metal coated PMMA particles 120 dispersed within a transparent polymer 110.

Example 1-Ethyl vinyl acetate with embedded silver coated poly (methyl methacrylate) spheres

Sustainable fuel generation via a photoelectrochemical (PEC) route has been a major area of research since the first report of solar water splitting on TiO₂, and the opportunities presented by PEC CO₂ reduction (CO₂R) have only increased research focus in this space. There has been strong interest in leveraging photovoltaic (PV) semiconductors as photoelectrodes for their optimized optoelectronic properties, but performance loss from degradation of these materials in aqueous environments remains a challenge. The protection of highly-optimized, high-performing semiconductors in PEC applications therefore remains an unachieved goal.

Semiconductor stability in aqueous electrochemical environments under illumination was established as a major barrier to PEC fuel production in the early days of the field. While the design of new semiconductors which do not degrade under operation remains attractive, the highly optimized semiconductors deployed in PV (e.g., Si, III-Vs, etc.) degrade under most illuminated, aqueous electrochemical conditions, especially as photocathodes. Protective schemes for PEC electrodes require a layer that (1) has minimal parasitic absorption above the semiconductor bandgap; (2) facilitates charge transfer to and from solution; and (3) prevents direct interaction of the electrolyte with the semiconductor, minimizing deleterious, non-fuel-forming reactions.

Some strategies have enabled dramatically improved photoelectrode lifetimes (including so-called “leaky” TiO₂ on Si and III-V electrodes, or MoS₂ on III-Vs). However, these approaches generally require complicated processing based on optimized chemistries which can be difficult to replicate or adapt to other semiconductors, and degradation can occur at pinholes or grain boundaries in the protective layer. Additionally, protective layers which are optimized to catalyze a particular reaction, such as MoS₂ on III-Vs for hydrogen evolution, cannot necessarily be adapted to drive other PEC fuel forming reactions such as CO₂R. Therefore, an additional criterion should be considered for protection strategies, that a layer (4) provide protection which is adaptable to new photoelectrode and catalyst chemistries, without substantial modification to the protective layer itself, which we term “agnostic”.

Recent work has shown promise in developing a protection scheme that meets this fourth criterion. Examples include (1) a metallic mesh infilled with epoxy to create a protective layer for a III-V multijunction photovoltaic (PV) for solar water splitting and (2) an integrated photovoltaic-electrochemical approach where catalyst microstructures were deposited on protective glass and electrically connected to an underlying III-V multijunction PV via metal shunts. Both approaches enable the separate processing of photoelectrodes from the protective layer, and provide physically robust protection schemes. However, the metallic mesh substantially shadows the underlying photoelectrode, dramatically reducing the photovoltage and photocurrent of the III-V PV. The geometry used in example (2) is limited to semiconductors with long diffusion lengths and good lateral transport, which often does not describe emerging photoelectrode materials.

To develop a photoelectrode-agnostic protection scheme, it is necessary to look beyond PEC fuel formation to areas where similar criteria (transparency, conductivity, and physical robustness) are met. These are the requirements for interlayers used to combine mechanically stacked photovoltaics (PVs) into tandem solar cells. Broadly, these layers utilize transparent polymers (often related to PV encapsulants, such as silicones and polyurethanes) with embedded materials (including nanomaterials and conductive organic polymers) that provide through-plane conduction. Laminating polymer sheets with embedded conductive materials between two sub cells enables the connection of dissimilar photovoltaics with negligible series resistance, such as a textured Si PV bottom cell with a GaInP top cell and Si integrated with perovskite PV as a two-junction device, among others.

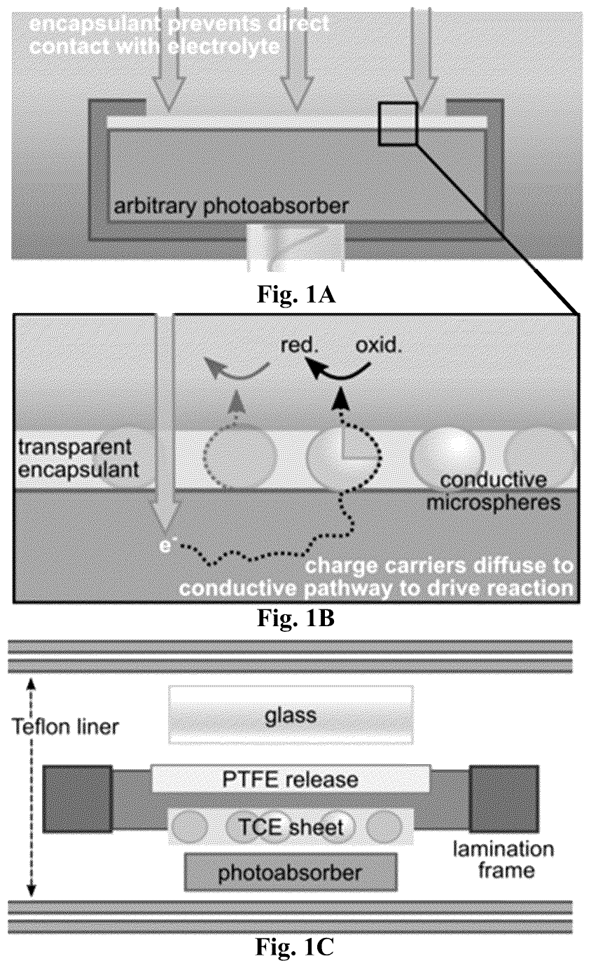

Described herein are transparent conductive encapsulants (TCEs) as protective layers for semiconductor photoelectrodes for PEC fuel formation. The example TCEs comprised of ethyl-vinyl acetate (EVA) with embedded silver-coated poly (methyl methacrylate) (Ag-PMMA) spheres create single-side contact to textured electrode surfaces while enabling conduction to an electrolyte and protecting the underlying semiconductor (shown in FIGS. 1A-1B). By optimizing the fabrication parameters, the electrochemical reduction of methyl viologen as a proxy system for fuel-forming reactions is also described herein.

The terms and expressions which have been employed herein are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments, exemplary embodiments and optional features, modification and variation of the concepts herein disclosed may be resorted to by those skilled in the art, and that such modifications and variations are considered to be within the scope of this invention as defined by the appended claims. The specific embodiments provided herein are examples of useful embodiments of the present invention and it will be apparent to one skilled in the art that the present invention may be carried out using a large number of variations of the devices, device components, methods steps set forth in the present description. As will be obvious to one of skill in the art, methods and devices useful for the present methods can include a large number of optional composition and processing elements and steps. The photoelectrode-agnostic properties of the TCE via application to multiple PV semiconductors are also described. Finally, long-term photoelectrochemical measurements confirm the efficacy of TCEs as protective layers by delaying the degradation of the underlying semiconductors.

The creation of protected electrodes and photoelectrodes begins with the fabrication of TCE sheets, which can be laminated to substrate surfaces. Toluene-dissolved EVA with dispersed ˜50 μm diameter Ag-coated PMMA spheres was blade coated onto PTFE-coated fiberglass to create ˜0.5 mm thick sheets (see Experimental Section infra for details). Following curing and removal from the PTFE support, the TCE sheets were cut to the approximate size of the substrate for lamination. Lamination thins the TCE sheet and slightly compresses the embedded Ag-PMMA spheres, ensuring exposed metal on both sides of the sheet. For previous work on applications where the sheets are laminated between rigid surfaces, such as PV subcell integration, pressures above 3 psi were sufficient to enable such contact. However, the lack of a rigid top surface to retain the compression of the Ag-PMMA spheres and prevent backflow of the EVA over the spheres initially resulted in TCE sheets that were not conductive, regardless of lamination pressure. Introduction of a removable rigid top surface (PTFE sheet backed by a glass substrate, FIG. 1C) enabled consistent through-sheet conduction.

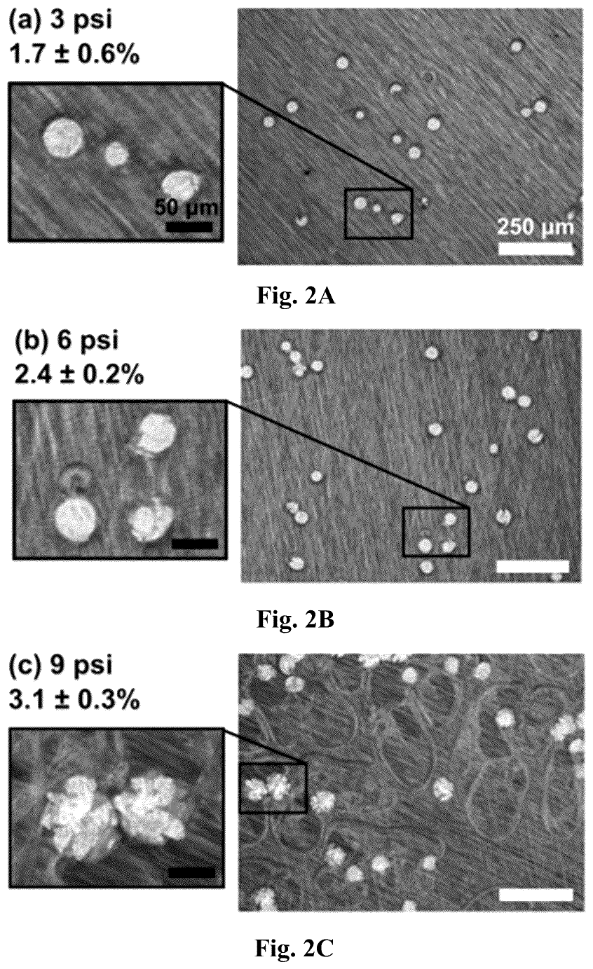

Lamination pressures were optimized to provide good electrical contact (determined electrochemically) without damage to the embedded Ag-PMMA spheres. Dry measurement of through-TCE conductivity was attempted by compressing the TCE-laminated substrate against a metal bar. Contact pressures were not reproducible, resulting in inconsistent measures of resistivity, and pressures sufficient to measure resistivity caused the TCE to cling to the metal contact and delaminate from the substrate, hindering subsequent electrochemical testing. FIGS. 2A-2C show optical micrographs of TCE from a single sheet laminated to as-sawn Si substrates at three different pressures for 10 minutes at 130° C. Average areal coverages of the Ag-PMMA spheres, hereafter referred to as coverage, were determined after lamination via image analysis at multiple locations on each electrode. At low pressure (3 psi), the TCE sheet was not reproducibly conductive due to uneven contacting of spheres, as illustrated by the disperse sizes. At high pressure (9 psi), most spheres were crushed, resulting in incomplete conduction pathways through the sheet.²⁸ In addition, smashing the spheres leaked PMMA into the EVA matrix, potentially distorting optical transmission due to different refractive indices of the polymers. At 6 psi, spheres present with consistent sizes and are substantially intact across the sheet. Some spheres are cracked but remain substantially intact, which maintains the conduction pathway through the TCE. The variation in lamination pressure influences the calculated coverage of the spheres, with the coverage at 6 psi (2.4±0.2%) matching the overall average of 2.4±0.7%.

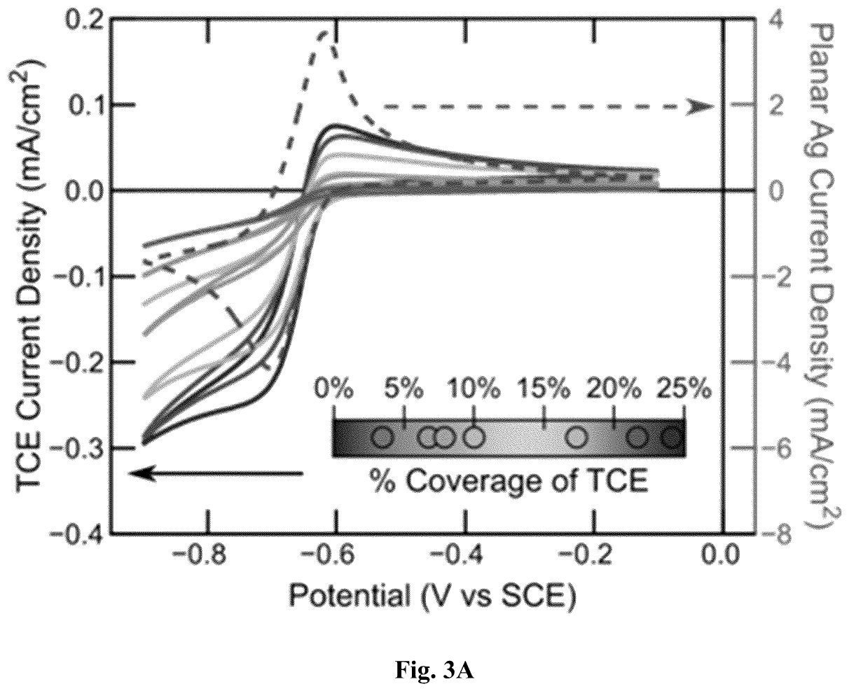

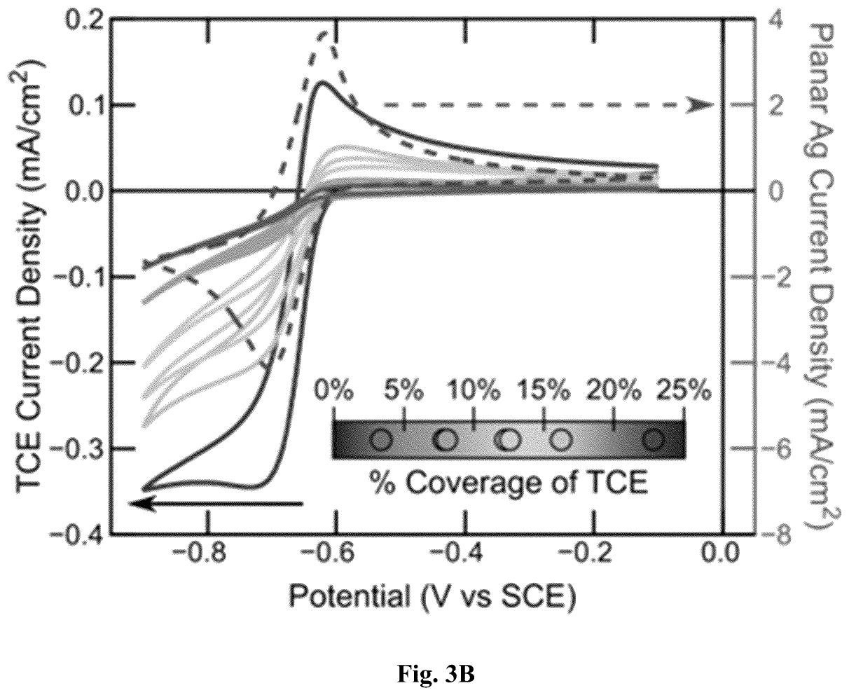

Titanium-coated as-sawn Si substrates were laminated with TCE sheets contacting the Ti and used as electrodes (hereafter, TCE|Ti|Si) to probe the electrochemical characteristics of the TCE. These substrates were selected to provide textured contact to the spheres, while also enabling a direct ohmic contact. Ag-PMMA coverages ranged between ˜3% and ˜24%, laminated at 6 and 7 psi to investigate the effect, if any, of varied pressures when the Ag-PMMA spheres remained intact. These electrodes were used to perform the first reduction of methyl viologen (MV) as shown in FIGS. 3A-3B. Because the currents are normalized to the geometric area for each electrode rather than the active area of Ag-PMMA spheres contacting the solution, current for the TCE|Ti|Si electrodes increases with increasing sphere coverage. Slightly higher currents at the same sphere coverage are observed for the electrodes laminated at 7 psi rather than at 6 psi, suggesting that a higher pressure better exposes the underlying Ag-PMMA spheres.

Overall, the electrodes display similar cyclic voltammetry (CV) characteristics to a Ag-coated planar Si electrode (hereafter, p-Ag|Si), which is shown for comparison. Planar Si was used rather than as-sawn to ensure that the geometric area of the electrode represented the electrochemically active area, which is not the case for rough surfaces. The reduction and subsequent oxidation of the MV on the TCE|Ti|Si electrodes is consistent with the process on the p-Ag|Si electrode: the half-wave potential E_{1/2} for both the 6 and 7 psi TCE|Ti|Si was −0.64±0.02 V vs SCE, which matches E_{1/2} for MV of p-Ag|Si at −0.658 V vs SCE. At the lowest sphere coverage, the separation of the oxidation and reduction peaks was wider than the ˜60 mV expected for a one-electron outer sphere reduction process, but the peak separation shrank with increasing coverage, until the highest coverage TCE|Ti|Si electrodes had peak-to-peak separation comparable to the p-Ag|Si.

While the oxidation wave of the CV for the TCE|Ti|Si electrodes shows normal mass-transport-limited current characteristics, the reduction current does not peak but rather flattens out at more negative voltage. This is attributed to the large geometric area which is not electrochemically active: although the electrode has reached a potential where MV can be reduced, a large reservoir persists in solution near the electrode surface and cannot readily diffuse to the small electrochemically active area. At the highest sphere coverage (FIGS. 3A-3B), the reduction wave approximates classical mass-transport-limited behavior. As coverage decreases, the hysteresis between the reduction and oxidation currents for each electrode also decreases, until the lowest coverage electrode displays almost no hysteresis. At this coverage, the Ag-PMMA spheres are well-dispersed and the TCE acts as an array of disc ultramicroelectrodes, with the Ag-PMMA spheres just reaching the critical radius of 25 μm.

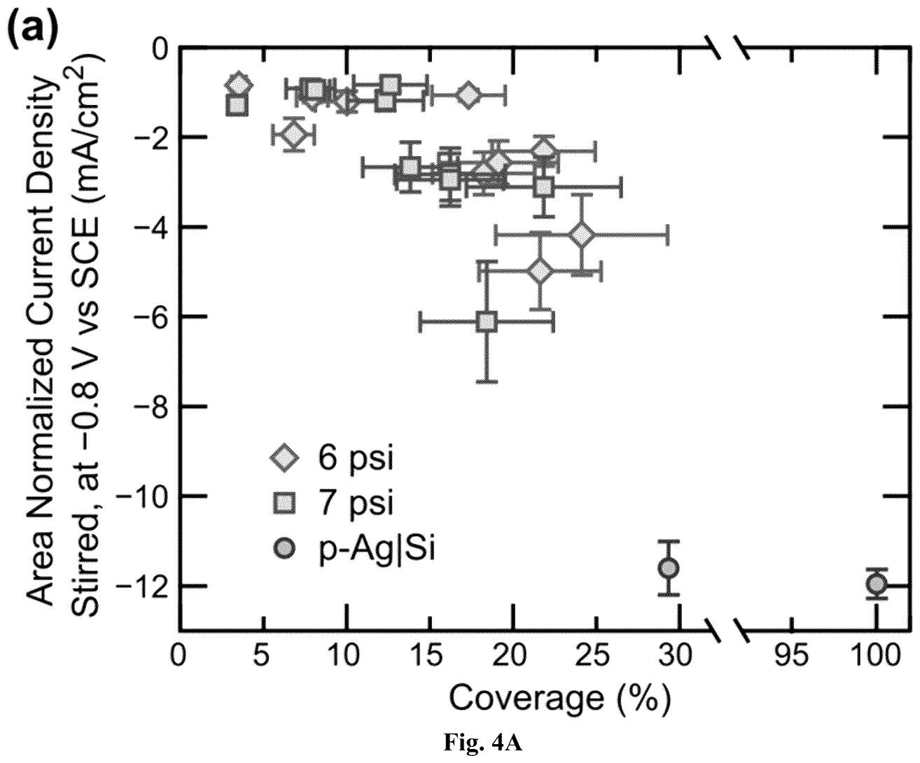

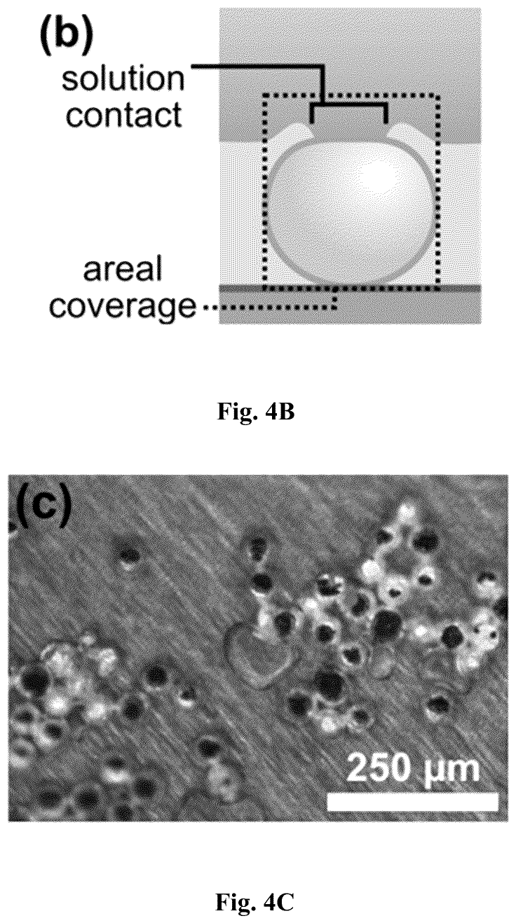

Voltammetry normalized to electrode area should result in increasing current with increasing Ag-PMMA sphere coverage in the TCE with the hypothetical 100% current being that of a planar Ag electrode. In comparison, normalization to the active area of the electrode (coverage×area) should result in the same current across all coverages (within the error of the area normalization) if all spheres provide through contact of the sheet. This relationship was verified by performing stirred CVs using the TCE|Ti|Si and p-Ag|Si electrodes. Normalized current densities at a fixed potential are shown in FIG. 4A. While lamination at 7 psi resulted in increased current densities normalized by electrode area for the unstirred CVs, stirring eliminates the difference between the two groups of electrodes; in the stirred data, the normalized current correlates only to TCE sphere coverage.

The difference between the coverage-normalized current densities of the TCE|TilSi electrodes and the p-Ag|Si electrode in FIG. 4A indicate that there are Ag-PMMA spheres in the TCE sheets which do not provide through-conduction. At coverages <15%, the normalized currents are nearly an order of magnitude lower than expected value set by the p-Ag|Si electrodes, while at coverages >15%, the value increases to about half that of the p-Ag|Si value. Because the coverages are measured based on optical microscopy and the EVA comprising the non-conductive part of the TCE is optically transparent, there is an opportunity for a discrepancy between the areal coverage of the Ag-PMMA and the area of the sphere that is actually exposed to the solution, even if the sphere is truly contacted to both, as shown in FIG. 4B. We were able to directly measure this phenomenon on some TCE|Ti|Si electrodes as a result of silver oxidation. Some electrodes were driven to oxidizing potentials in the course of measurement and were later found to have a black contaminant on the Ag-PMMA spheres (FIG. 4C). We attribute this to the oxidation of silver only at the area which was directly exposed to the electrolyte. This experimental confirmation of FIG. 4B indicates that coverages calculated based on optical microscopy represent an upper bound on the true exposed area of the Ag-PMMA spheres.

TABLE 1
Lamination pressure, coverage, and geometric areas of all
TCE|Ti|Si electrodes. Photoelectrode Protection

| Electrode | TCE Lamination Pressure | Coverage | Geometric Area |
|---|---|---|---|
| Type | (psi) | (percent) | (cm²) |
| TCE\|Ti\|Si | 6 | 3.5 ± 0.4 | 0.65 |
| | | 6.8 ± 1.3 | 0.53 |
| | | 7.9 ± 0.9 | 0.26 |
| | | 10.0 ± 1.9 | 0.64 |
| | | 17.3 ± 2.2 | 0.29 |
| | | 18.2 ± 3.1 | 0.36 |
| | | 19.1 ± 3.6 | 0.55 |
| | | 21.6 ± 3.7 | 0.80 |
| | | 21.8 ± 3.1 | 0.42 |
| | | 24.1 ± 5.2 | 0.86 |
| | 7 | 3.4 ± 0.6 | 0.75 |
| | | 7.8 ± 1.5 | 0.70 |
| | | 8.1 ± 0.9 | 0.57 |
| | | 12.3 ± 2.3 | 0.47 |
| | | 12.6 ± 2.2 | 0.58 |
| | | 13.8 ± 2.9 | 0.55 |
| | | 16.2 ± 3.3 | 0.37 |
| | | 16.2 ± 3.2 | 0.73 |
| | | 18.4 ± 4.0 | 0.70 |
| | | 21.8 ± 4.6 | 0.42 |
| p-Ag\|Si | N/A | 100 | 0.48 |
| | | 29.3 | 0.14 |
| | | (exposed | |
| | | Ag area) | |

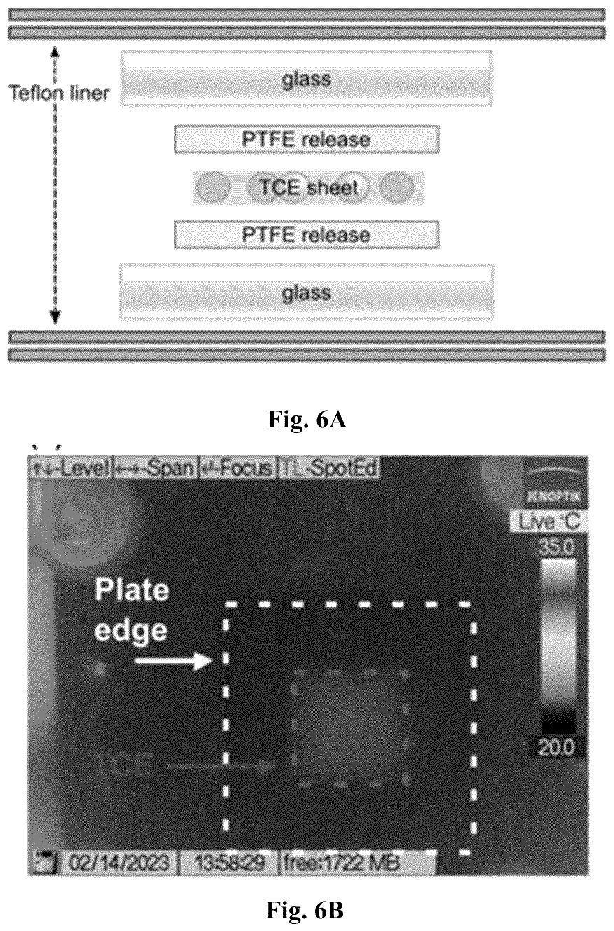

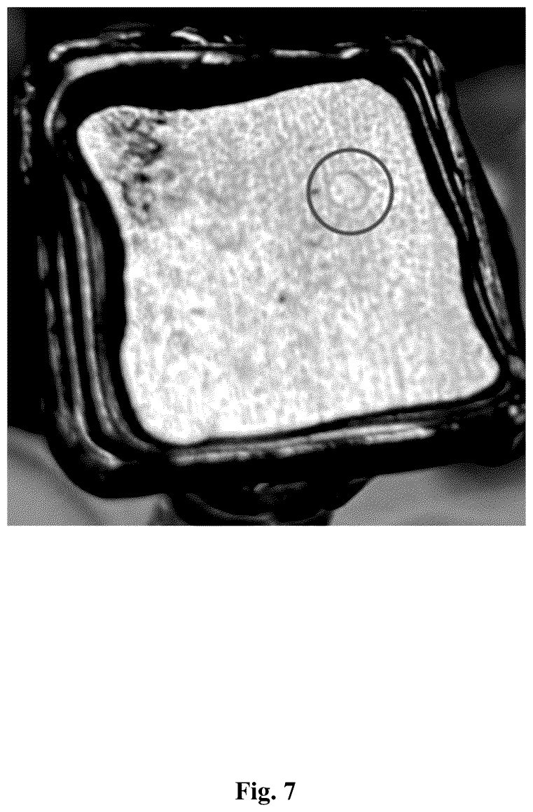

Following demonstration of the electrochemical function of TCEs, photoactive semiconductors were used as substrates to confirm the photoabsorber-agnostic properties of the TCE protection scheme. TCE sheets were laminated directly to smooth, planar p-type GaInP and Si and the performance for the MV^{2+/+} reduction was compared to that of bare photoelectrodes (complete details for photoelectrodes are given in Table 2). These measurements are primarily to address the electrochemical function of the TCE sheets in this application, because as a PV encapsulant, EVA is optically transparent and previous work has demonstrated that TCE sheets are highly transparent even with coverages up to 33%. Thus, light loss to the photoactive substrates from the TCE sheets is minimal and due only to Ag-PMMA sphere shading. Although the TCE sheets are initially pinhole-free (FIGS. 6A-6B) and no macroscopic changes were noted for the TCE|Ti|Si electrodes, extended operation did result in obvious leaking of electrolyte under the TCE sheet for a few photoelectrodes (FIG. 7). The results presented here are from photoelectrodes with no visible changes following testing.

TABLE 2
Reaction chemistry, coverage, and lamination
pressure details of all photoelectrodes.

| | | | TCE | | |
|---|---|---|---|---|---|
| | | | Lamination | | Geometric |
| Photo- | Redox | | Pressure | Coverage | Area |
| absorber | Couple | Electrode | (psi) | (percent) | (cm²) |
| p-GaInP | MV^{2+/+} | Bare p- | N/A | N/A | 0.55 |
| | | GaInP | | | |
| | | TCE\|p- | 7 | 20.78 ± | 0.67 |
| | | GaInP | | 5.6%* | |
| p-Si | MV^{2+/+} | Bare p-Si | N/A | N/A | 0.60 |
| | | TCE\|p-Si | 7 | 32.10 ± | 0.87 |
| | | | | 4.4% | |
| | Hydrogen | Bare p-Si | N/A | N/A | 0.74 |
| | evolution | TCE\|p-Si | 7 | 32.51 ± | 1.04 |
| | (pH 11) | | | 6.6% | |

*Note that this sample has high standard deviation in coverage at ~27%.

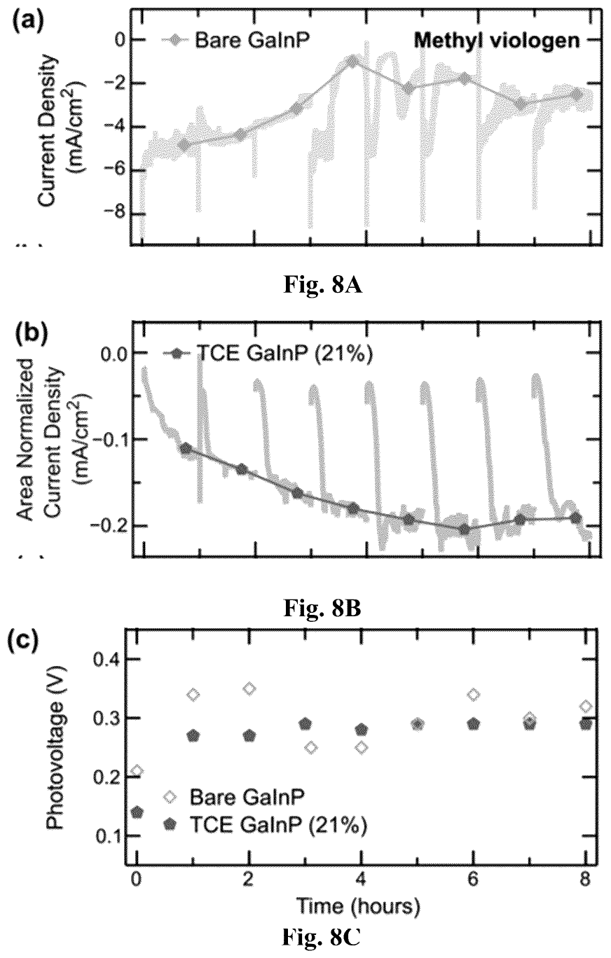

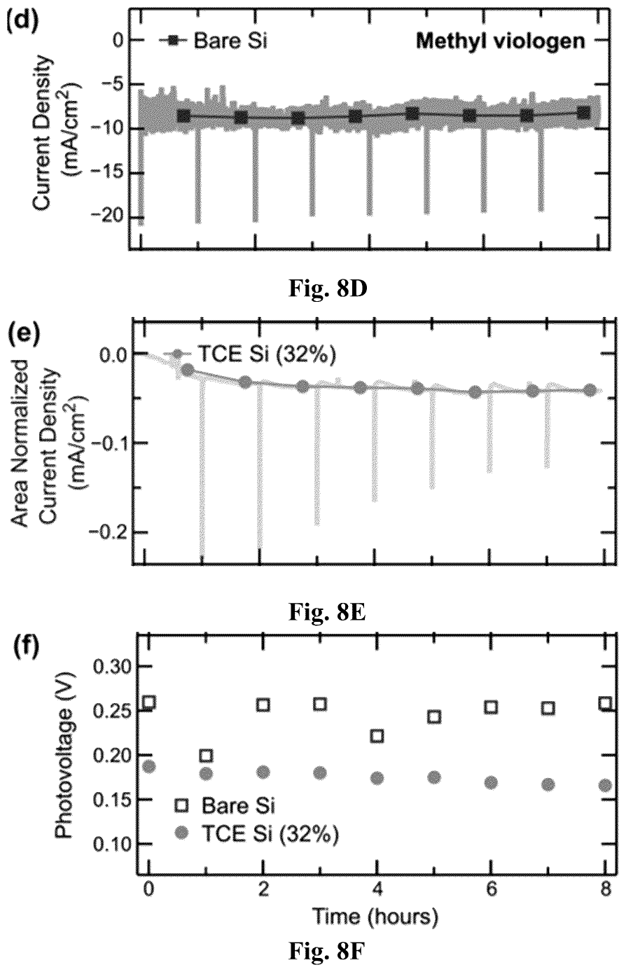

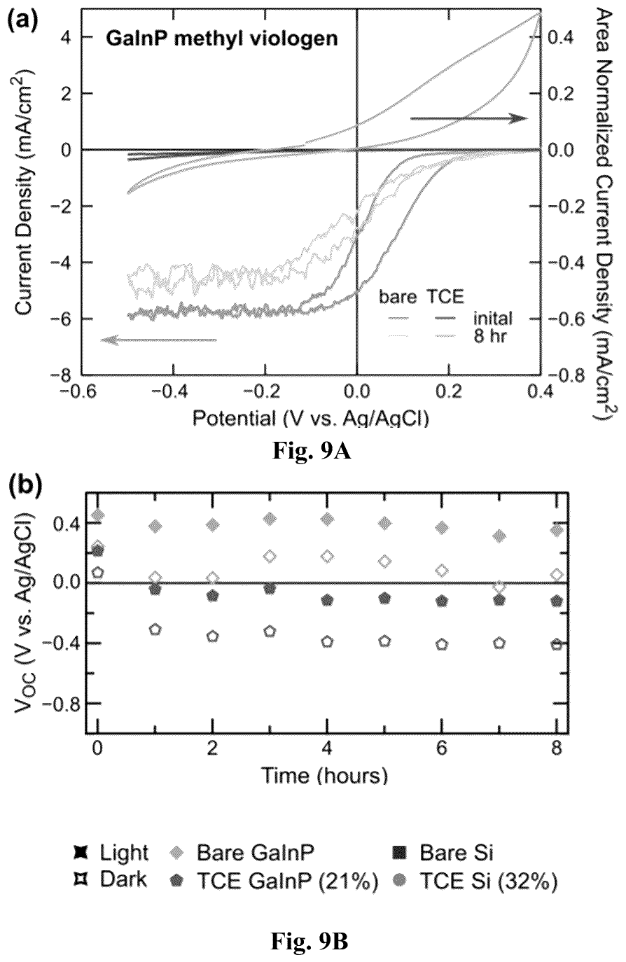

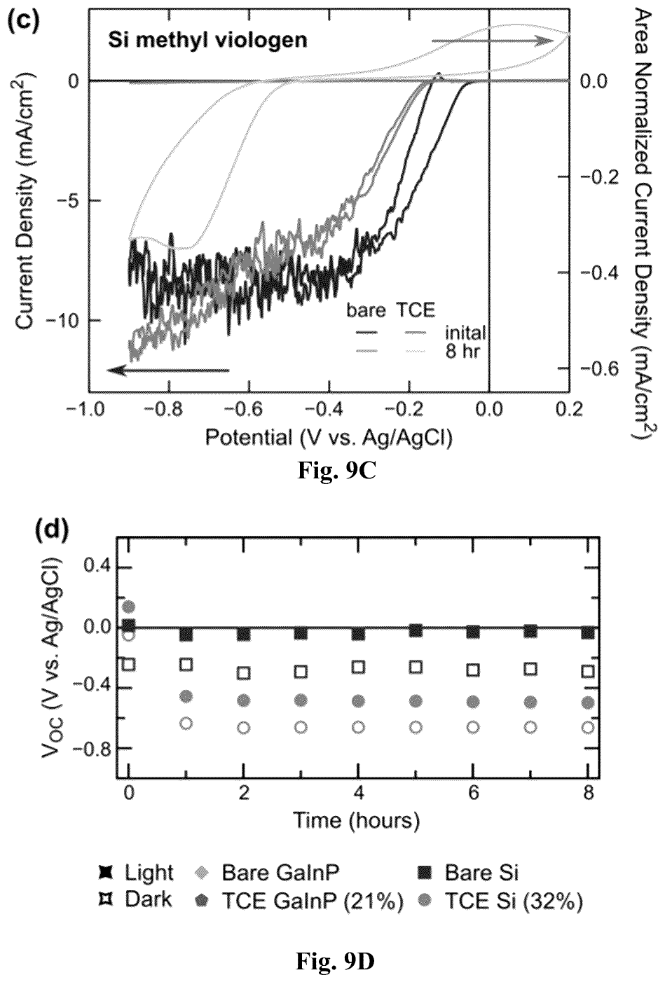

Extended photoelectrode studies were conducted under the same MV²⁺⁺ aqueous electrolyte conditions used previously (FIGS. 8A-8F). Open circuit voltage (V_{OC}) measurements and CVs were performed under simulated solar irradiation and in the dark. A potential negative of the onset of MV²⁺ reduction on each type of bare photoelectrode was selected for chronoamperometry (CA, sec FIGS. 9A-9D for CVs). The bare and TCE-protected photoelectrodes were operated under illumination at the specified potential for eight hours in one-hour increments, with dark and illuminated V_{OC} and CVs measured initially and at each hour.

Over the period of CA operation, the bare GaInP photoelectrode slowly loses current density magnitude and performs inconsistently, while the photocurrent magnitude of the TCE GaInP gradually improves (FIGS. 8A-8B). The photovoltage (difference between illuminated and dark V_{OC}) of the bare GaInP is initially larger but decreases over the course of the measurement, while the photovoltage of the TCE GaInP is stable after the first hour (FIGS. 8C). Similar trends were observed for the Si photoelectrodes. The bare and TCE Si photoelectrodes have very stable CA performance, with a slight increase in the magnitude of the TCE Si photocurrent over time, similar to that observed for the TCE GaInP photoelectrode (FIGS. 8D-8E). More photocurrent and photovoltage loss is expected for the TCE Si photoelectrode as the TCE coverage is very high, and sphere area is proportional to light blockage. At 32% coverage, the TCE should transmit about 60% of visible light. As with the GaInP photoelectrodes, the photovoltage of the bare Si photoelectrode is less stable than that of the TCE Si photoelectrode, although the photovoltage of the TCE Si photoelectrode declines slightly over the eight-hour course of the measurement (FIG. 8F).

The stability of the photocurrent and photovoltage for the TCE-protected photoelectrodes is remarkable. For both GaInP and Si, the TCE is contacted directly to the bare, smooth and planar semiconductor surface (for Si, following HF removal of surface oxide). As noted for the TCE|Ti|Si electrodes, the current density of the TCE-protected photoelectrodes is substantially smaller than that of the bare photoelectrodes, even when normalized to the active area of the Ag-PMMA spheres in the TCE sheet rather than the geometric area and accounting for shading. We attribute the current density reduction to both overestimation of the number of contacted Ag-PMMA spheres and the resistivity of the Ag|semiconductor interface. Overestimation of contacted spheres is exacerbated for the planar semiconductor substrates compared to the Ti|Si used previously, as the smooth surfaces likely reduce the area of the Ag|semiconductor interface. The resistivity of the Ag|semiconductor interface is expected to be quite high as neither the GaInP or Si is as highly doped as a contact layer would be in a PV, limiting current output. Contact resistivity also contributes to the difference between the photovoltage of the bare Si and TCE Si due to the very low doping of the Si. Despite the high contact resistivity, consistent current extraction was obtained using the TCE sheets for both GaInP and Si, and the current density was particularly more stable for the TCE GaInP compared to the bare GaInP photoelectrode.

While the TCE-protected photoelectrodes do have shifted V_{OC} values compared the bare photoelectrodes (see FIG. 8C, 8F, 9A-9D), the photovoltage is similar to the bare semiconductor in both protected cases. The slight reduction in photovoltage of the TCE-protected photoelectrodes may be an acceptable trade-off for a more stable photovoltage than a bare photoelectrode provides. It should be noted that V_{OC} is different between the TCE Si and GaInP electrodes despite being in the same electrolyte, indicating that charge carriers are not simply being transferred into the electrolyte at the Ag/Ag⁺ potential. The change in absolute V_{OC} with TCE application is likely also an effect of the Ag|semiconductor contact resistivity, which could be improved with future optimization.

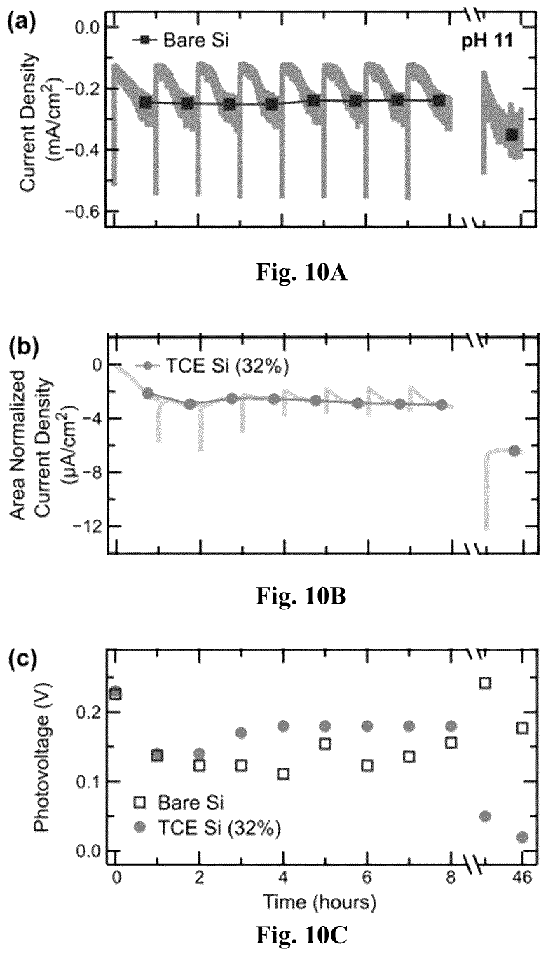

In addition to investigating the long-term reduction of MV^{2+/+}, the behavior of a TCE-protected Si photoelectrode was compared to a bare Si photoelectrode for performing hydrogen evolution in pH 11 buffer, as the stability of Si photoelectrodes is substantially lower under basic conditions. The same procedure was followed, with eight hours of CA interrupted at each hour by V_{OC} and CV measurements (FIGS. 10A-10C). Following those eight hours, the photoelectrodes were disconnected and allowed to sit in the pH 11 electrolyte for an extended period with no illumination; a final CA was measured after forty-five hours as well as final V_{OC} and CV measurements which were taken at the beginning and end of the final CA.

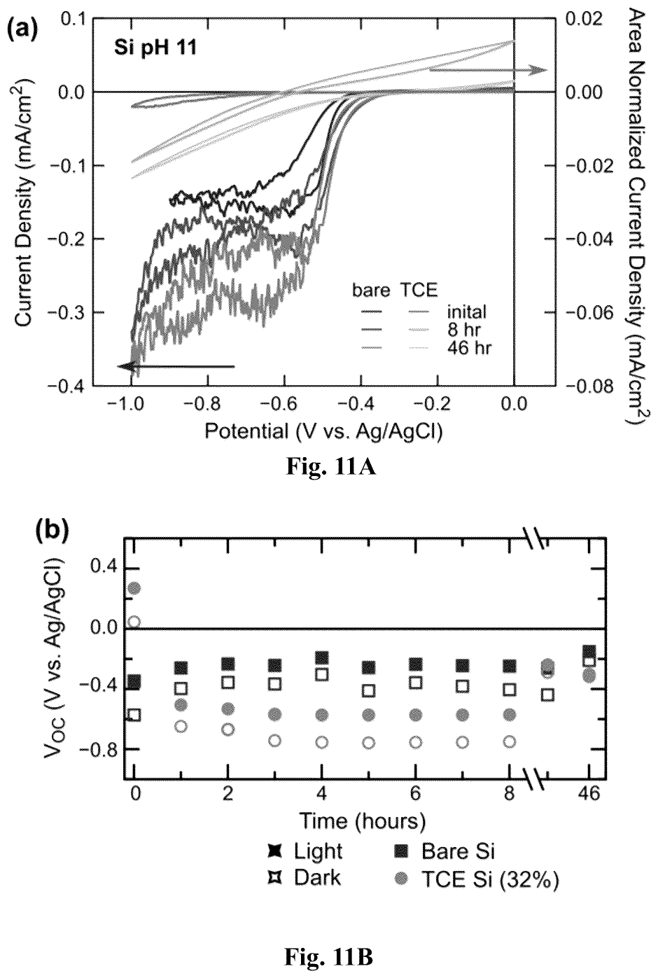

Like the behavior of the Si photoelectrodes in the methyl viologen electrolyte, the photocurrents of the bare and TCE Si electrodes are very stable over the first eight hours in pH 11 buffer (FIGS. 10A-10B). Following the extended rest in the electrolyte, the photocurrent magnitude increased for both the bare and TCE Si photoelectrodes, with the photocurrent magnitude of the TCE Si photoelectrode more than doubling. This may be a result of slow electrolyte penetration around the edge of the Ag-PMMA spheres, increasing the TCE active area. The photovoltage of the bare Si photoelectrode varies over the measurement period, while the photovoltage of the TCE Si photoelectrode increases over the first few hours and then stabilizes around 0.18 V (FIG. 10C, see FIGS. 11A-11B for complete V_{OC} measurements). Unlike the Si photoelectrodes in MV^{2+/+} electrolyte, there is more voltage extracted from the TCE Si than the bare Si in pH 11, even though the coverage of the TCE is similar, due to changes in the surface energetics of Si in high pH environments.

After the extended rest in pH 11, however, the TCE Si has almost no photovoltage despite the improved current from the CA, while the bare Si photovoltage increased substantially. Although there is no visible permeation of the TCE protection by electrolyte, and the Ag-PMMA spheres did not visibly change as they had in FIG. 10C, the loss of photovoltage indicates changes to the Ag|semiconductor interface which should be investigated further for long-term operation of a TCE-protected photoelectrode. This may result from slow permeation of moisture into the EVA, changing the Si surface, and is a point of investigation for further development.

### CONCLUSION

Transparent conductive encapsulants based on EVA and Ag-PMMA microspheres are described herein for electrochemical applications and characterized electrochemically and as photoelectrochemical protective layers. The adaptation from photovoltaic encapsulant to photoelectrode protective layer required modifications to the lamination process, to ensure that the Ag-PMMA spheres remained exposed for electrochemical contact. Electrochemical characterization of the TCE showed comparable characteristics to a planar Ag electrode, although not all of the Ag-PMMA spheres provided through-TCE conduction based on normalized cyclic voltammetry, confirmed by optical microscopy of oxidized TCE electrodes.

### Experimental Section

TCE Fabrication and % Coverage Calculation. Toluene, ethyl-vinyl acetate (EVA) pellets (DuPont, 33% vinyl acetate), and silver coated poly (methyl methacrylate) (Ag-PMMA) microspheres (Cospheric, diameter 45-53 μm, 250 nm Ag coating) were mixed and blade coated to a thickness of 0.5 mm. After curing at 100° C. for ten minutes and subsequent cooling, TCE sheets were released from the PTFE-coated fiberglass backing and cut to the approximate size of the electrode substrate using a razor blade. The electrode and TCE were then assembled into the full lamination stack (FIG. 1C). The stack was pressed in a Bent River SPL5080 Solar Panel Laminator at pressures between 3 and 9 psi at 130° C. for 10 minutes. Lamination temperature was initially varied but found to have little impact through-conductivity of the TCE sheets; TCE mechanical strength was maintained as long as the lamination temperature was above 100° C.

Coverage of Ag-PMMA microspheres in the TCE sheets was determined after lamination via analysis of 5-7 optical microscope images taken across each electrode using a Nikon Eclipse LV100 optical microscope. Binary filtering and calculation of the average area coverage was performed using ImageJ. As noted, coverage is influenced by the lamination pressure of the TCE sheet. Due to large spatial variation in the coverage of the TCE sheets, only electrodes and photoelectrodes with standard deviation <22% of the average coverage were included.

A lab-built pinhole detection apparatus (PDA) was used to investigate the presence of pinholes in the TCE sheets prior to lamination. Whole TCE sheets were laminated between two sheets of smooth PTFE, then peeled from the PTFE for examination. For analysis, the TCE sheet was supported by a metal frame with a 1 in² opening, covered with a Pt-coated gas diffusion electrode (GDE) and rubber frame, and clamped into place. During a PDA test, hydrogen flows beneath the sheet and any hydrogen that escapes through pinholes reacts exothermically with the Pt-coated GDE, which is recorded by an IR camera. No such reactions were observed during testing, indicating that no hydrogen passed through the TCE sheet and that the sheets are initially pinhole frec.

Electrode Fabrication. As-sawn Si (Topsil-ascut CZ (100), 1-5 Ωcm) was used as the substrate for the TCE|Ti|Si electrodes. Following a one-minute dip in 10% HF to remove surface oxide, 100 nm Ti was electron-beam deposited on both sides of the Si. The Ag|Ti|Si electrode used single-side polished planar Si (University Wafer CZ (100), 0.001-0.005 Ωcm). Following HF oxide removal, 100 nm Ti was electron-beam deposited on both sides, followed by evaporation of 50 nm Ag on the front. The GaInP photoelectrodes were p-type GaInP (1×10¹⁸ cm⁻³) on a p-GaAs substrate, grown in-house at the National Renewable Energy Laboratory. A gold back contact was electroplated to the GaInP. The Si photoelectrodes were p-type (1.0072 Ωcm, Virginia Semi), with ohmic back contacts provided by gallium-indium eutectic. Prior to TCE lamination or photoelectrochemistry on the bare photoelectrode, the Si was dipped in 10% HF to remove any oxide. For all electrodes, silver paint (Ted Pella leitsilber 200) was used to connect the ohmic, metal back contact to tinned copper wire fed through glass tubing for electrode fabrication. Following a drying step, the wire and electrode were sealed with epoxy (Loctite EA E-60HP, 3M DP 420 NS, DP 110 gray, or EA 9460) to the glass tubing to isolate the electrodes from the solution; both electrodes and photoelectrodes were made to be downward-facing during electrochemical operation. After epoxy curing, the exposed, geometric electrode areas were measured with a HP Scanjet 7650 scanner and analyzed with Image J.

(Photo) electrochemical Characterization. A Biologic SP-300 Potentiostat was used for all electrochemical and photoelectrochemical measurements. For measurements of TCE characteristics (FIGS. 3 and 4), a 45 mM methyl viologen (methyl viologen dichloride hydrate 98%) in 0.5 M K₂SO₄ (Sigma-Aldrich, ≥99.0%) electrolyte was used, with a Pt counter electrode and saturated calomel reference electrode. An electrolyte containing only 0.5 M K₂SO₄ was used to measure capacitance. Stirred and unstirred cyclic voltammetry was measured: Ti on Si was scanned −0.9 V to −0.1 V vs SCE. Si PEC CV was scanned −0.7 V to 0.2 V vs Ag/AgCl. GaInP was scanned −0.5 to 0.4 V vs Ag/AgCl, scanning negative at rates of 5, 20, and 100 mV s⁻¹ for multiple cycles to ensure reproducibility.

Following electrochemical measurements, some electrodes were broken from their glass tubing and examined the optical microscope. Electrodes which were driven to positive voltage (+0.2 V vs SCE) had Ag-PMMA spheres with a black contaminant, as shown in FIG. 4C. The black contaminant is attributed to oxidized silver on the Ag-PMMA spheres as a result of the applied bias, which is much greater than the required bias to oxidize silver. These optical microscope images confirm the schematic in FIG. 4B, illustrating that the calculated coverages of Ag-PMMA spheres based on optical microscopy represents an upper bound on the possible coverage. For photoelectrode measurements, a 45 mM methyl viologen in 0.5 M K₂SO₄ electrolyte was used as above, with a Pt counter electrode and Ag/AgCl reference electrode. An ABET Technologies Sun 3000 Solar Simulator light source was used for illuminated measurements.

### Supporting Information

TCE Sheet Characterization. A transparent conductive encapsulant (TCE) sheet was laminated between two pieces of glass and smooth polytetrafluoroethylene (PTFE) sheets (Fig. Sla) to replicate the electrode lamination process (FIG. 6A) and allow for direct characterization of the unsupported TCE sheet using a lab-built pinhole detection apparatus (PDA). The laminated TCE sheet was peeled from the PTFE and loaded into the PDA, supported by a metal frame with a 1 in² opening. During a PDA measurement, hydrogen flows beneath the surface being examined, and any hydrogen that escapes through pinholes reacts exothermically with a Pt-coated GDE, which is recorded by an IR camera. No such reactions were observed during testing (FIG. 6B), indicating that the TCE sheets are initially pinhole frec.

TCE|Ti|Si Electrodes. Because Ag-PMMA spheres tend to agglomerate during the sheet casting process, the TCE sheets had spatially varied coverage. The coverage of each laminated substrate was measured individually prior to fabrication into an electrode, and the distribution in coverage values for each electrode is captured by the standard deviations reported for the average coverage. Only substrates with a standard deviation of less than 22% of the average coverage were measured as electrodes.

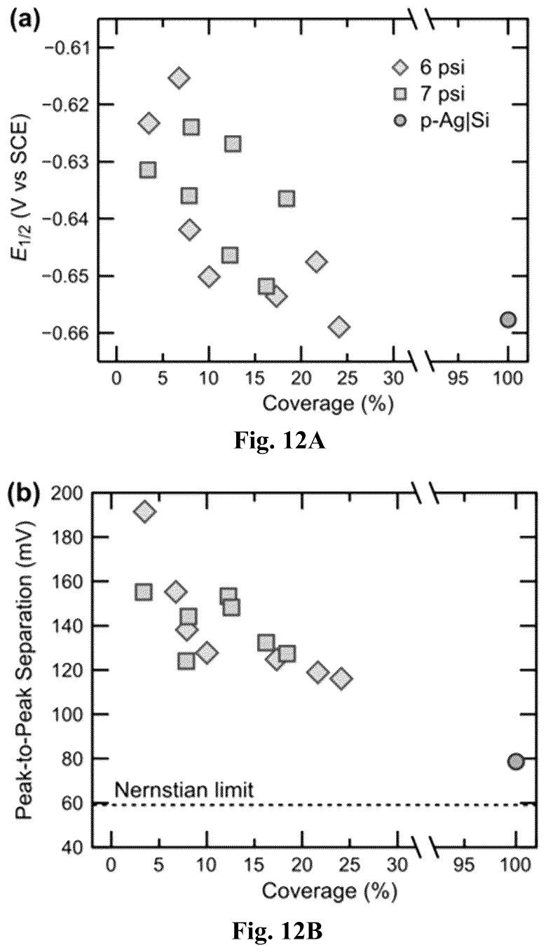

The electrochemical characteristics of the TCE|Ti|Si electrodes in MV^{2+/+} are broadly similar to the planar Ag|Si electrode, as expected based on the fact that Ag-PMMA spheres provide the reduction sites in the TCE-based electrodes. The half-wave potential, E_{1/2}, is very similar to that of the p-Ag|Si and becomes more similar as the coverage increases (FIG. 12A). The peak-to-peak separation for the reduction and oxidation waves for MV^{2+/+} is wide on the electrodes with the lowest coverage and decreases as coverage increases (FIG. 12B).

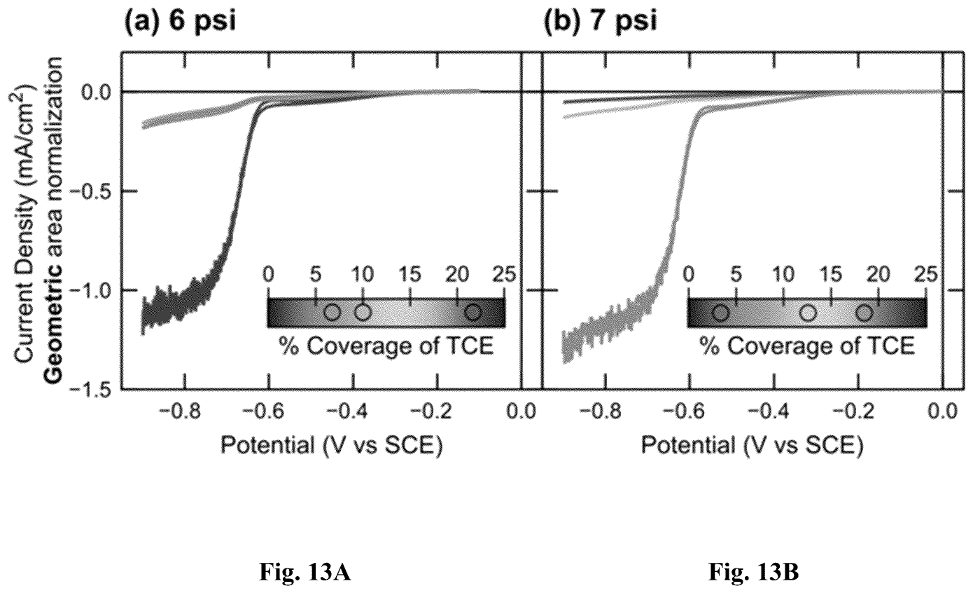

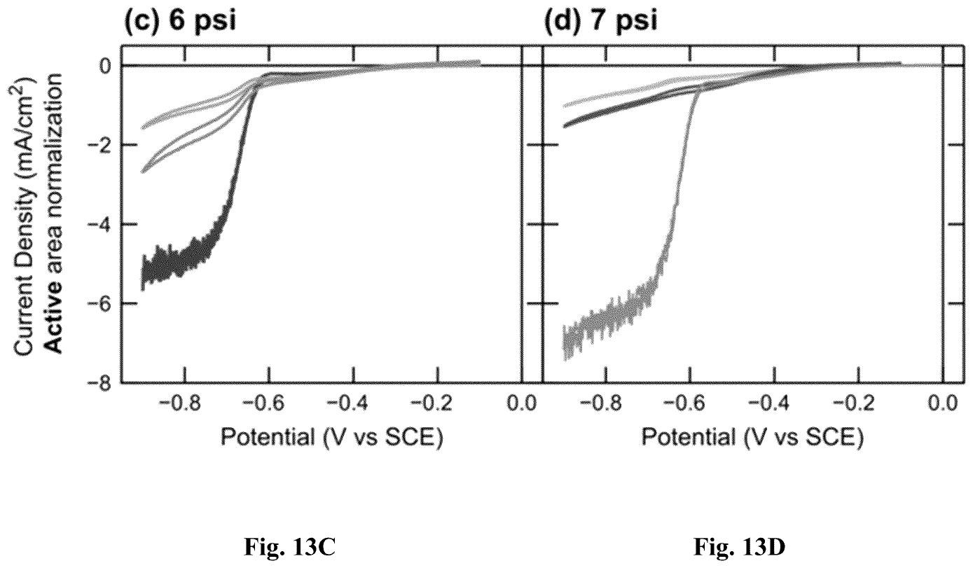

FIGS. 13A-13D shows the full CV scans for representative low, medium, and high coverage TCE|Ti|Si electrodes at both 6 and 7 psi with both geometric and active area normalizations; these data were processed into the data shown in FIG. 4. As noted in the main text, the electrodes should all have the same current density when normalized to the active area of the electrode, if all Ag-PMMA spheres are contacted to both the substrate and the electrolyte; the differences in the current density after rescaling indicate that some spheres are not contacted. Stirred electrochemistry was initially performed on the p-Ag|Si electrode as described in the main text. The electrode was then manually masked with a resist (nail polish), thus reducing the area that could participate in electrochemistry in subsequent measurements. For both cases, the exposed Ag area was found via filtering scanned images, as described herein.

The present invention may be further understood by the following non-limiting examples:
Example 1. An encapsulant comprising:
   a transparent polymer; and
   a plurality of transition metal coated rigid polymer particles embedded in the transparent
   polymer;
   wherein the plurality of transition metal coated rigid polymer particles provide a conductive pathway through the transparent polymer.
Example 2. The encapsulant of example 1, wherein the transparent polymer comprises ethyl vinyl acetate (EVA), a silicone, a polyurethane or a combination thereof.
Example 3. The encapsulant of example 1 or 2, wherein the transition metal comprises Cu, Ag, Au, Pd, Pt, Al or a combination thereof.
Example 4. The encapsulant of example 1 or 2, wherein the transition metal comprises Ag.
Example 5. The encapsulant of any of examples 1-4, wherein a portion of the transition metal coated rigid polymer particles are exposed in a top surface and a bottom surface of the transparent polymer.
Example 6. The encapsulant of any of examples 1-5, wherein the plurality of transition metal coated rigid polymer particles comprise a coverage of the encapsulant selected from the range of 3% to 25%.
Example 7. The encapsulant of any of examples 1-6, wherein the thickness of the encapsulant is about equal to the effective diameter of the transition metal coated rigid polymer particles.
Example 8. The encapsulant of any of examples 1-7, wherein the transition metal coated rigid polymer particles are substantially spherical.
Example 9. The encapsulant of any of examples 1-8 further comprising a photoelectrode proximate to the encapsulant.
Example 10. The encapsulant of any of examples 1-9, wherein the rigid polymer particles comprise poly (methyl methacrylate) (PMMA).
Example 11. A device comprising:
   a photoelectrode; and
   an encapsulant comprising:
      a transparent polymer comprising EVA; and
      a plurality of silver coated poly (methyl methacrylate) (PMMA) particles embedded in the transparent polymer;
      wherein the plurality of silver coated PMMA particles provide a conductive pathway through the transparent polymer;
   wherein a first surface of the encapsulant is proximate to a surface of the photoelectrode.
Example 12. The device of example 11, wherein the photoelectrode is a photocathode.
Example 13. The device of example 11 or 12 further comprising an electrolyte, wherein the electrolyte is proximate to a second surface of the encapsulant.
Example 14. A method comprising:
   providing a rigid bottom surface;
   depositing a solution comprising a plurality of transition metal coated PMMA spheres in a dissolved polymer on the surface of the bottom surface;
   applying a top surface barrier, wherein the solution is positioned between the bottom surface and the top surface barrier;
   evaporating a solvent from the dissolved polymer to form a solid transparent polymer with dispersed transition metal coated PMMA spheres; and
   applying a pressure to the solid transparent polymer, thereby exposing a portion of the dispersed transition metal coated PMMA spheres and generating a transparent conductive encapsulant.
Example 15. The method of example 14, wherein the solid transparent polymer comprises EVA.
Example 16. The method of example 14 or 15, wherein the transition metal comprises Ag.

Example 17. The method of any of examples 14-16, wherein the right bottom surface and top surface barrier comprise polytetrafluoroethylene (PTFE) and glass.
Example 18. The method of any of examples 14-17, wherein the pressure is less than or equal to 7 psi or 48.3 kPa.
Example 19. The method of any of examples 14-18, further comprising:
   removing the rigid bottom surface and the top surface barrier from the solid transparent polymer with dispersed transition metal coated PMMA spheres; and
   applying the solid transparent polymer with dispersed transition metal coated PMMA spheres to a photoelectrode.

As used herein and in the appended claims, the singular forms “a”, “an”, and “the” include plural reference unless the context clearly dictates otherwise. Thus, for example, reference to “a cell” includes a plurality of such cells and equivalents thereof known to those skilled in the art. As well, the terms “a” (or “an”), “one or more” and “at least one” can be used interchangeably herein. It is also to be noted that the terms “comprising”, “including”, and “having” can be used interchangeably. The expression “of any of claims XX-YY” (wherein XX and YY refer to claim numbers) is intended to provide a multiple dependent claim in the alternative form, and in some embodiments is interchangeable with the expression “as in any one of claims XX-YY.”

When a group of substituents is disclosed herein, it is understood that all individual members of that group and all subgroups, are disclosed separately. When a Markush group or other grouping is used herein, all individual members of the group and all combinations and subcombinations possible of the group are intended to be individually included in the disclosure. For example, when a device is set forth disclosing a range of materials, device components, and/or device configurations, the description is intended to include specific reference of each combination and/or variation corresponding to the disclosed range.

Every formulation or combination of components described or exemplified herein can be used to practice the invention, unless otherwise stated.

Whenever a range is given in the specification, for example, a density range, a number range, a temperature range, a time range, or a composition or concentration range, all intermediate ranges and subranges, as well as all individual values included in the ranges given are intended to be included in the disclosure. It will be understood that any subranges or individual values in a range or subrange that are included in the description herein can be excluded from the claims herein.

All patents and publications mentioned in the specification are indicative of the levels of skill of those skilled in the art to which the invention pertains. References cited herein are incorporated by reference herein in their entirety to indicate the state of the art as of their publication or filing date and it is intended that this information can be employed herein, if needed, to exclude specific embodiments that are in the prior art. For example, when composition of matter is claimed, it should be understood that compounds known and available in the art prior to Applicant's invention, including compounds for which an enabling disclosure is provided in the references cited herein, are not intended to be included in the composition of matter claims herein.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. In each instance herein any of the terms “comprising”, “consisting essentially of” and “consisting of” may be replaced with either of the other two terms. The invention illustratively described herein suitably may be practiced in the absence of any element or elements, limitation or limitations which is not specifically disclosed herein.

All art-known functional equivalents, of any such materials and methods are intended to be included in this invention. The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

What is claimed is:

1. An encapsulant comprising:
a transparent polymer; and
a plurality of transition metal coated rigid polymer particles embedded in the transparent polymer;
wherein the plurality of transition metal coated rigid polymer particles provide a conductive pathway through the transparent polymer.

2. The encapsulant of claim 1, wherein the transparent polymer comprises ethyl vinyl acetate (EVA), a silicone, a polyurethane or a combination thereof.

3. The encapsulant of claim 1, wherein the transition metal comprises Cu, Ag, Au, Pd, Pt, Al or a combination thereof.

4. The encapsulant of claim 1, wherein the transition metal comprises Ag.

5. The encapsulant of claim 1, wherein a portion of the transition metal coated rigid polymer particles are exposed in a top surface and a bottom surface of the transparent polymer.

6. The encapsulant of claim 1, wherein the plurality of transition metal coated rigid polymer particles comprise a coverage of the encapsulant selected from the range of 3% to 25%.

7. The encapsulant of claim 1, wherein the thickness of the encapsulant is about equal to the effective diameter of the transition metal coated rigid polymer particles.

8. The encapsulant of claim 1, wherein the transition metal coated rigid polymer particles are substantially spherical.

9. The encapsulant of claim 1 further comprising a photoelectrode proximate to the encapsulant.

10. The encapsulant of claim 1, wherein the rigid polymer particles comprise poly (methyl methacrylate) (PMMA).

11. A device comprising:
a photoelectrode; and
an encapsulant comprising:
a transparent polymer comprising EVA; and
a plurality of silver coated poly (methyl methacrylate) (PMMA) particles embedded in the transparent polymer;
wherein the plurality of silver coated PMMA particles provide a conductive pathway through the transparent polymer;
wherein a first surface of the encapsulant is proximate to a surface of the photoelectrode.

12. The device of claim 11, wherein the photoelectrode is a photocathode.

13. The device of claim 11 further comprising an electrolyte, wherein the electrolyte is proximate to a second surface of the encapsulant.

14. A method comprising:
providing a rigid bottom surface;
depositing a solution comprising a plurality of transition metal coated PMMA spheres in a dissolved polymer on the surface of the bottom surface;
applying a top surface barrier, wherein the solution is positioned between the bottom surface and the top surface barrier;
evaporating a solvent from the dissolved polymer to form a solid transparent polymer with dispersed transition metal coated PMMA spheres; and
applying a pressure to the solid transparent polymer, thereby exposing a portion of the dispersed transition metal coated PMMA spheres and generating a transparent conductive encapsulant.

15. The method of claim 14, wherein the solid transparent polymer comprises EVA.

16. The method of claim 14, wherein the transition metal comprises Ag.

17. The method of claim 14, wherein the right bottom surface and top surface barrier comprise polytetrafluoroethylene (PTFE) and glass.

18. The method of claim 14, wherein the pressure is less than or equal to 7 psi or 48.3 kPa.

19. The method of claim 14, further comprising:
removing the rigid bottom surface and the top surface barrier from the solid transparent polymer with dispersed transition metal coated PMMA spheres; and
applying the solid transparent polymer with dispersed transition metal coated PMMA spheres to a photoelectrode.
